(19) United States
(12) Patent Application Publication
(10) Pub. No.: US 2018/0234087 A1
(43) Pub. Date: Aug. 16, 2018

(54) SIGNAL SELECTION CIRCUIT AND SEMICONDUCTOR DEVICE

(71) Applicant: SII Semiconductor Corporation, Chiba-shi (JP)

(72) Inventors: Masakazu SUGIURA, Chiba-shi (JP); Hideyuki SAWAI, Chiba-shi (JP)

(21) Appl. No.: 15/826,022

(22) Filed: Nov. 29, 2017

(30) Foreign Application Priority Data
Feb. 13, 2017 (JP) 2017-023941

(51) Int. Cl. H03K 17/042

(52) U.S. Cl. CPC H03K 17/04206

(57) ABSTRACT

Provided is a signal selection circuit including a control circuit capable of generating a drive signal having a fast rise/fall time. A positive feedback circuit is provided to the control circuit, which generates the drive signal for controlling a plurality of switches configured to switch an input signal to provide the signal to an output terminal.

### RELATED APPLICATIONS

This application claims priority under 35 U.S.C. § 119 to Japanese Patent Application No. 2017-023941 filed on Feb. 13, 2017, the entire content of which is hereby incorporated by reference.

### BACKGROUND OF THE INVENTION

### 1. Field of the Invention

The present invention relates to a signal selection circuit which includes a control device configured to drive switch units, and a semiconductor device.

### 2. Description of the Related Art

In a peak hold circuit or a zero-drift amplifier of chopper, there has been used a signal selection circuit configured to switch input signals to provide the signals to output terminals.

FIG. 5 is a circuit diagram for illustrating a related-art signal selection circuit 500.

The signal selection circuit 500 switches input signals input from an input terminal IA and IB, and provides them an output terminal OA and OB through control of a switch 511 to a switch 514 by a clock signal input to a clock terminal CLK (see, for example, FIG. 3 and FIG. 4 of Japanese Patent Application Laid-open No. 2010-141406).

For example, when the clock terminal CLK is at a low level, the switches 511 and 514 are on and the switches 512 and 513 arc off. Thus, the signal from the input terminal IA is provided to the output terminal OA, and the signal from the input terminal IB is provided to the output terminal OB. When the clock terminal CLK is at a high level, the switches 511 and 514 are off and the switches 512 and 513 are on. Thus, the signal from the input terminal IB is provided to the output terminal OA, and the signal from the input terminal IA is provided to the output terminal OB.

In the related-art signal selection circuit 500, however when a rise/fall time of the clock signal is not short enough, the switches 511 and 514 which are driven by the clock signal, and the switches 512 and 513 which are driven by a drive signal Φx obtained by inverting the clock signal by an inverter 503, are both on simultaneously even for a short period of time.

### SUMMARY OF THE INVENTION

It is an object of the present invention to provide a signal selection circuit, which is capable of eliminating a period of time in which selector switches configured to select signals are on simultaneously only by adding a simple circuit.

According to one embodiment of the present invention, there is provided a signal selection circuit including: a first switch arranged between a first input terminal and a first output terminal; a second switch arranged between a second input terminal and the first output terminal; a third switch arranged between the first input terminal and a second output terminal; a fourth switch arranged between the second input terminal and the second output terminal; and a control circuit configured to: receive a clock signal from a clock input terminal; and provide a first control signal for controlling the first switch and the fourth switch, and a second control signal for controlling the second switch and the third switch, the control circuit including: a first inverter connected to the clock input terminal; and a positive feedback circuit connected to both ends of the first inverter.

According to a signal selection circuit of the present invention, the rise/fall time of the drive signal which is generated by the control circuit including the positive feedback circuit becomes shorter, and hence it is possible to eliminate the period of time in which the switches of the signal selection circuit are on simultaneously. Accordingly, it is possible to provide a signal selection circuit having an output signal of excellent quality.

### BRIEF DESCRIPTION OF THE DRAWINGS

FIG. 1 is a circuit diagram of a signal selection circuit including a control circuit according to an embodiment of the present invention.

FIG. 2 is a circuit diagram for illustrating another example of the control circuit of the embodiment.

FIG. 3 is a circuit diagram for illustrating still another example of the control circuit of the embodiment.

FIG. 4 is a circuit diagram for illustrating yet another example of the control circuit of the embodiment.

FIG. 5 is a circuit diagram for illustrating a related-art signal selection circuit.

### DETAILED DESCRIPTION OF THE PREFERRED EMBODIMENTS

Now, an embodiment of the present invention is described in detail with reference to the drawings.

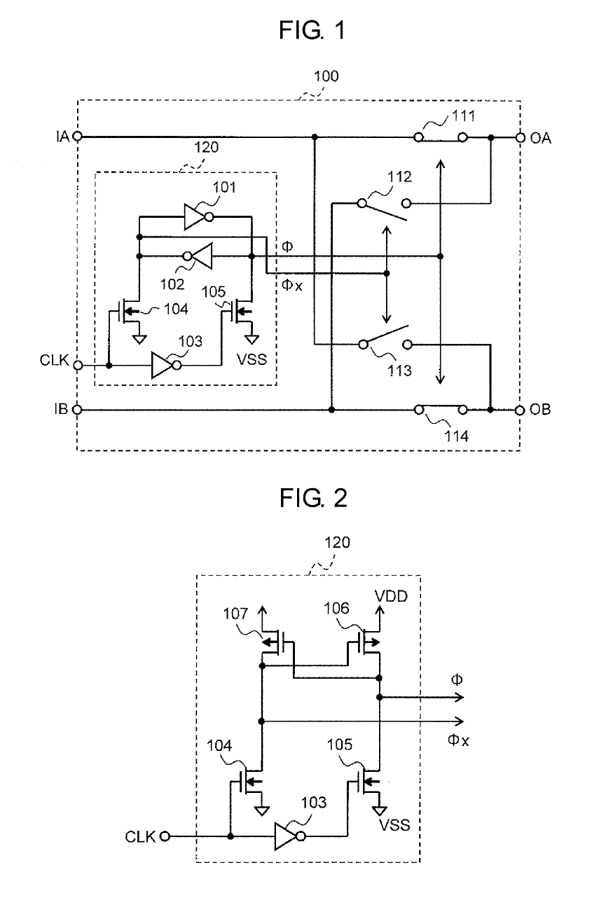

FIG. 1 is a circuit diagram of a signal selection circuit including a control circuit according to the embodiment of the present invention.

The signal selection circuit 100 of this embodiment includes a control circuit 120 configured to receive an input clock signal to generate a signal to drive switches, and a plurality of switches 111 to 114 configured to switch input signals to output the signals to output terminals.

The control circuit 120 includes inverters 101, 102, and 103, and NMOS transistors 104 and 105.

The inverter 103 has an input terminal connected to a clock terminal CLK, and an output terminal connected to a gate of the NMOS transistor 105. An input terminal and an output terminal of the inverter 101, and an output terminal and an input terminal of the inverter 102 are connected to each other, respectively. The NMOS transistor 104 has a gate connected to the clock terminal CLK, a drain connected to the input terminal of the inverter 101, and a source connected to a ground terminal VSS. The NMOS transistor 105 has a drain connected to the input terminal of the inverter 102, and a source connected to the ground terminal VSS. The inverter 101 is configured to provide a drive signal Φ from its output terminal. The inverter 102 is configured to output a drive signal Φx from its output terminal.

The switch 111 is connected between an input terminal IA and an output terminal OA, and controlled by the drive signal Φ. The switch 112 is connected between an input terminal IB and the output terminal OA, and controlled by the drive signal Φx. The switch 113 is connected between the input terminal IA and an output terminal OB, and controlled by the drive signal Φx. The switch 114 is connected between the input terminal IB and the output terminal OB, and controlled by the drive signal Φ.

The inverter 101 and the inverter 102 construct a positive feedback circuit forming a positive feedback loop. The positive feedback circuit operates to shorten both of the rise/fall times of the drive signal Φ and the rise/fall times of the drive signal Φx each other.

When the clock signal input to the clock terminal CLK becomes a high level, the NMOS transistor 104 is controlled to be on, and hence the drive signal Φx changes to a low level. At this time, the input terminal of the inverter 101 changes to a low level, and hence the output terminal of the inverter 101, that is, the drive signal Φ changes to a high level. Further, the input terminal of the inverter 102 also changes to a high level, and hence the output terminal of the inverter 102, that is, the drive signal Φx further changes to a low level.

When the clock signal becomes a low level, the NMOS transistor 105 is controlled to be on, and hence the drive signal Φ changes to a low level. At this time, the input terminal of the inverter 102 changes to a low level, and hence the output terminal of the inverter 102, that is, the drive signal Φx changes to a high level. Further, the input terminal of the inverter 101 also changes to a high level, and hence the output terminal of the inverter 101, that is, the drive signal Φ increasingly changes to a low level.

With the positive feedback circuit constructed by the above-mentioned inverters 101 and 102, the control circuit 120 can generate the drive signals Φ and Φx having shorter rise/fall times.

Accordingly, the switches 111 to 114 are driven by the drive signals Φ and Φx having short rise/fall times. Thus, it is possible to eliminate the period of time in which the switches 111 and 114, and the switches 112 and 113 are on simultaneously.

As described above, according to the signal selection circuit including the control circuit of this embodiment, the rise/fall times of the drive signal, which are generated by the control circuit including the positive feedback circuit, become shorter, and hence it is possible to eliminate the period of time in which the switches are on simultaneously. Accordingly, it is possible to provide the signal selection circuit having the output signal of excellent quality.

FIG. 2 is a circuit diagram for illustrating another example of the control circuit of this embodiment.

The control circuit 120 of FIG. 2 includes PMOS transistors 106 and 107, the NMOS transistors 104 and 105, and the inverter 103. Specifically, in the control circuit 120 of FIG. 2, the inverters 101 and 102 of the control circuit 120 of FIG. 1 are formed by the PMOS transistors 106 and 107.

The PMOS transistor 106 has a gate connected to the drain of the NMOS transistor 104, a drain connected to the source of the NMOS transistor 105, and a source connected to a power supply terminal VDD. The PMOS transistor 107 has a gate connected to the drain of the NMOS transistor 105, a drain connected to the source of the NMOS transistor 104, and a source connected to the power supply terminal VDD.

The control circuit 120 of FIG. 2 is a positive feedback circuit in which the PMOS transistors 106 and 107 form a positive feedback loop. Accordingly, it is apparent that the control circuit 120 of FIG. 2 exerts the same effect as that of the control circuit 120 of FIG. 1.

Through setting of a driving capacity of the NMOS transistors 104 and 105 to be higher than that of the PMOS transistors 106 and 107, it is possible to further eliminate the state in which the drive signal Φ and the drive signal Φx cause the switches 111 and 114, and the switches 112 and 113 to be on simultaneously.

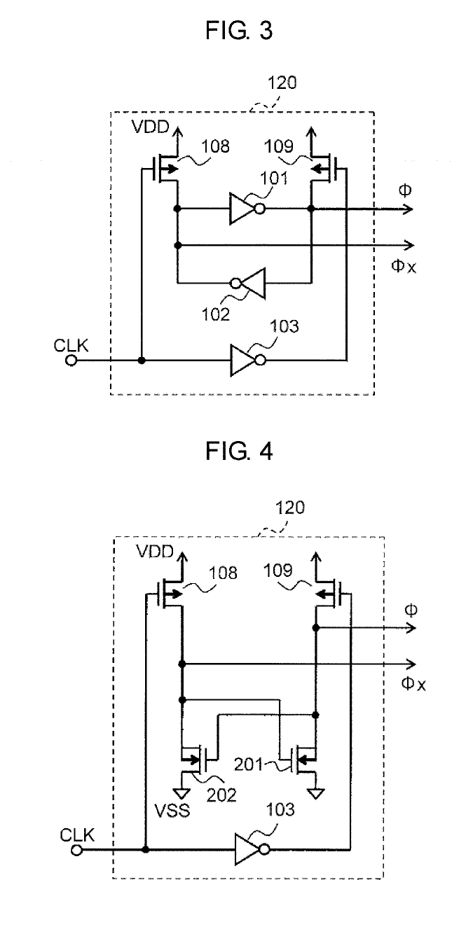

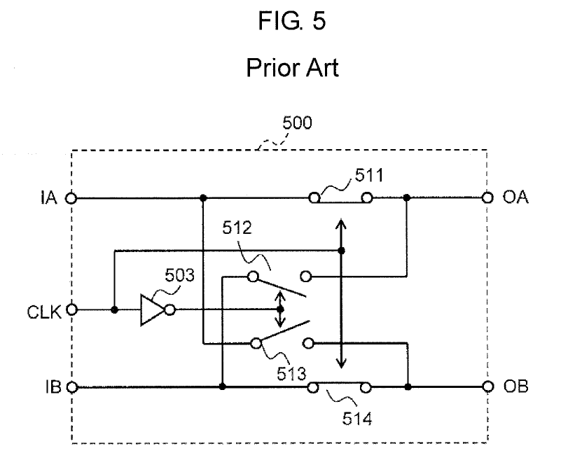

FIG. 3 is a circuit diagram for illustrating still another example of the control circuit of this embodiment.

The control circuit 120 of FIG. 3 includes PMOS transistors 108 and 109 and the inverters 101, 102, and 103. Specifically, the control circuit 120 of FIG. 3 has a configuration in which the NMOS transistors 104 and 105 of the control circuit 120 of FIG. 1 are replaced by the PMOS transistors 108 and 109.

The PMOS transistor 108 has a gate connected to the clock terminal CLK, a drain connected to the input terminal of the inverter 101 and the output terminal of the inverter 102, and a source connected to the power supply terminal VDD. The PMOS transistor 109 has a gate connected to the output terminal of the inverter 103, a drain connected to the output terminal of the inverter 101 and the input terminal of the inverter 102, and a source connected to the power supply terminal VDD.

It is apparent that the control circuit 120 of FIG. 3 is the same as the control circuit 120 of FIG. 1 in that the inverter 101 and the inverter 102 form the positive feedback loop, and that the effect of the control circuit 120 of FIG. 3 is also the same as that of the control circuit 120 of FIG. 1.

FIG. 4 is a circuit diagram for illustrating yet another example of the control circuit of this embodiment.

The control circuit 120 of FIG. 4 includes NMOS transistors 201 and 202, the PMOS transistors 108 and 109, and the inverter 103. Specifically, in the control circuit 120 of FIG. 4, the inverters 101 and 102 of the control circuit 120 of FIG. 3 are formed by the NMOS transistors 201 and 202.

The PMOS transistor 108 has the gate connected to the clock terminal CLK, the drain connected to a drain of the NMOS transistor 202 and a gate of the NMOS transistor 201, and the source connected to the power supply terminal VDD. The PMOS transistor 109 has the gate connected to the output terminal of the inverter 103, the drain connected to a gate of the NMOS transistor 202 and a drain of the NMOS transistor 201, and the source connected to the power supply terminal VDD. The NMOS transistors 201 and 202 each have a source connected to the ground terminal VSS.

In the control circuit 120 of FIG. 4, the NMOS transistors 201 and 202 form the positive feedback loop. Accordingly, it is apparent that the control circuit 120 of FIG. 4 exerts the same effect as that of the control circuit 120 of FIG. 1.

The PMOS transistors 108 and 109 have a driving capacity higher than that of the NMOS transistors 201 and 202. It is therefore possible to further eliminate the state in which the drive signal Φ and the drive signal Φx cause the switches 111 and 114, and the switches 112 and 113 to be on simultaneously.

As described above, according to the signal selection circuit including the control circuit of the present invention, the rise/fall time of the drive signal which is generated by the control circuit including the positive feedback circuit becomes shorter, and hence it is possible to eliminate the period of time in which the switches are on simultaneously. Accordingly, it is possible to provide the signal selection circuit having the output signal of excellent quality.

The present invention is not limited to the above-mentioned embodiment, and various modifications can be made thereto without departing from the gist of the present invention.

The signal selection circuit of the present invention is suitable for a signal selection circuit of a peak hold circuit or a zero-drift amplifier of a chopping type.

What is claimed is:

1. A signal selection circuit, comprising:
a first switch arranged between a first input terminal and a first output terminal;
a second switch arranged between a second input terminal and the first output terminal;
a third switch arranged between the first input terminal and a second output terminal;
a fourth switch arranged between the second input terminal and the second output terminal; and
a control circuit configured to
output a first control signal for controlling the first switch and the fourth switch, and a second control signal for controlling the second switch and the third switch by a clock signal provides from a clock input terminal,
the control circuit comprising:
a first inverter connected to the clock input terminal; and
a positive feedback circuit connected to both ends of the first inverter.

2. A signal selection circuit according to claim 1, wherein the positive feedback circuit comprises:
a first MOS transistor having a gate connected to an input terminal of the first inverter;
a second MOS transistor having a gate connected to an output terminal of the first inverter;
a second inverter having an input terminal connected to a drain of the first MOS transistor, and an output terminal connected to a drain of the second MOS transistor; and
a third inverter having an input terminal connected to the drain of the second MOS transistor, and an output terminal connected to the drain of the first MOS transistor.

3. A semiconductor device, comprising the signal selection circuit of claim 1.

4. A semiconductor device, comprising the signal selection circuit of claim 2.
